(19) United States
(12) Patent Application Publication
(10) Pub. No.: US 2003/0029833 A1
(43) Pub. Date: Feb. 13, 2003

(54) High speed photoresist stripping chamber

(76) Inventor: Wayne L Johnson, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/204,448

(22) PCT Filed: Mar. 20, 2001
(86) PCT No.: PCT/US01/05821

(30) Foreign Application Priority Data
Mar. 20, 2000 (US) 60190099

(51) Int. Cl. C23C 16/00; C23F 1/00

(52) U.S. Cl. 216/58; 118/719; 118/723 I; 118/723 MP; 156/345.31; 156/345.32; 156/345.38; 156/345.48

(57) ABSTRACT

A method and system for stripping a photoresist layer quickly. A pre-processing element (e.g., a pre-heater, pre-cooler, or pre-clamper) is integrated into a load lock chamber to increase throughput of the system. While a first wafer is processed inside a processing chamber, a second wafer is pre-processed using the pre-processing element.

### CROSS-REFERENCE TO RELATED CO-PENDING APPLICATIONS

This application is related to the following co-pending applications: U.S. Provisional Application No. 60/156,595, entitled “Multi-Zone Resistance Heater,” filed Sep. 29, 1999; and PCT application PCT/US 98/23248, entitled “All RF Biasable and/or Surface Temperature Controlled ESRF,” filed Nov. 13, 1998. This application is also related to the following two applications filed on even date herewith: attorney docket No. 2312-0780-6YA PROV entitled “High Speed Stripping for Damaged Photoresist” and attorney docket No. 2312-0836-6YA PROV entitled “Chuck Transport Method and System.” Each of those four co-pending applications is incorporated herein by reference in its entirety.

### BACKGROUND OF THE INVENTION

1. Field of the Invention

The present invention is directed to a method and system for increasing the throughput of a plasma processing system by decreasing the amount of time that a wafer spends in a processing chamber, and more particularly to a method and system for using a pre-heated substrate/wafer holder to heat a substrate prior to inserting the substrate in the processing chamber.

2. Discussion of the Background

U.S. Pat. No. 5,478,403 (Shinagawa et al., 1995) introduces an apparatus for resist ashing applications. The apparatus uses a microwave source to generate the oxygen-containing plasma. As shown in FIG. 1, the microwave-generated plasma is introduced to a downstream process chamber, where the resist-coated wafer is to be treated, through a plasma-transmitting plate. While microwaves are efficient in generating oxygen radicals, the ions in the plasma may have high ion energy and cause charge damage and contamination if in direct contact with the wafer surface. Those ions must be eliminated from the flux on their way from the plasma source to the wafer substrate. The transmitting plate captures charged particles in the plasma while allowing the transmission of neutral active species to thereby ash the photoresist coating without accumulating charges on the wafer surface. The wafer is placed on a chuck that is capable of adjusting its position to vary the distance between the wafer and the plasma transmitting plate.

Similar concepts of using microwave-generated plasma in resist stripping can be found in U.S. Pat. No. 5,562,775 (Mihara et al., 1996), U.S. Pat. No. 5,780,395 (Sydansk et al., 1998), U.S. Pat. No. 5,773,201 (Fujimura et al., 1998), and U.S. Pat. No. 5,545,289 (Chen et al., 1996). As described therein, the wafers to be processed are placed downstream from the plasma source chamber. The ions generated by the microwave source recombine on the way to the wafer so that only neutral radicals reach the wafer and affect the ashing process.

If a downstream approach is not used, the wafer is placed close to the plasma source, and a charge trapping plate or grid is generally used in order to minimize charge damage. The use of a transmitting plate to eliminate the charged particles from reaching the wafer surface is discussed in U.S. Pat. No. 4,859,303 (Kainitsky et al., 1989) and “Advanced photoresist strip with a high pressure ICP source” (Savas et al., Solid State Technology, October 1996, pp. 123-128) (hereinafter “Savas”).

U.S. Pat. No. 4,861,424 (Fujimura et al., 1989) (hereinafter “the '424 patent”) describes a two-step process designed specifically for stripping ion-implanted photoresist. It uses a gaseous mixture of hydrogen and nitrogen in the first processing step and oxygen plasma (or a wet-chemistry procedure) in the second processing step. Using hydrogen in the first step, the bonds that join an implanted ion with carbon atoms in the carbonized region (for example, phosphorus-carbon bonds), can be broken and a hydride of the implanted ion (phosphine, in this example) can be produced. The resulting hydrides are volatile, even at room temperature. In the '424 patent, the first step is performed in a parallel plate RIE (reactive ion etching) mode reactor and the second step in a microwave downstream asher, as shown in FIG. 2. There are two problems associated with this approach. The first problem is that the plasma produced in a parallel plate RIE mode reactor has high electron temperatures and high ion energies that may cause charge and lattice damage to and contamination of the substrate.

Savas describes a resist stripping system that utilizes an inductively coupled plasma source with a Faraday shield to reduce RF capacitive coupling to the plasma. The nearly pure inductive coupling reduces the plasma potential. The use of high pressure (˜1 Torr) and low RF power level (˜1 W/cc) produces a plasma with high dissociation and low ionization. Thus this source provides a high resist stripping rate but very low charge damage. However, as the ashing of photoresist is the result of chemical reactions. a high ashing rate requires a high wafer temperature (e.g., between 200° C.-250° C.). Therefore, due to the high wafer temperature, the system still has a potential resist popping problem when it is used for stripping ion implanted photoresist at high etch rates. On the other hand, when a low processing temperature is used, the ashing rate is compromised, resulting in lower throughput.

Commercial plasma processing systems are very expensive. As a result, to recoup the investment in those systems, system users attempt to process as many wafers per system per day as possible. In some processes, however, the time required to heat-up a substrate once it is in a plasma processing chamber can significantly increase the total time that the substrate spends in the processing chamber. Moreover, the time required to clamp a substrate to the processing chuck (and to test the clamping of the substrate) once the substrate is in the plasma processing chamber is often not negligible.

### SUMMARY OF THE INVENTION

Accordingly, it is an object of the present invention to provide an improved method and system for increasing the throughput of a plasma processing system.

This and other advantages are made possible by a processing chamber that pre-processes (e.g., pre-heats, pre-cools and/or pre-clamps), outside of a processing chamber. a substrate (e.g., a wafer) that is to be processed inside the processing chamber. Embodiments of the pre-processing apparatus according to the present invention include a pre-heating wafer holder (or chuck). The pre-heating chuck may be transferred with the wafer into the processing chamber or it may remain outside of the processing chamber while the wafer is transferred into the processing chamber.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is a cross-section of a microwave system from U.S. Pat. No. 5,478,403;

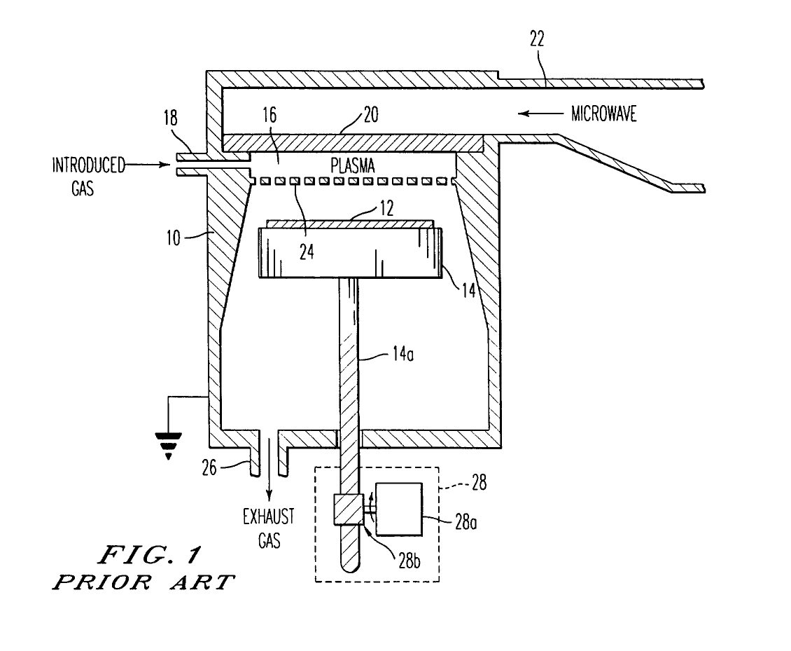

FIG. 2 is schematic illustration of a two-chamber system disclosed in U.S. Pat. No. 4,861,424;

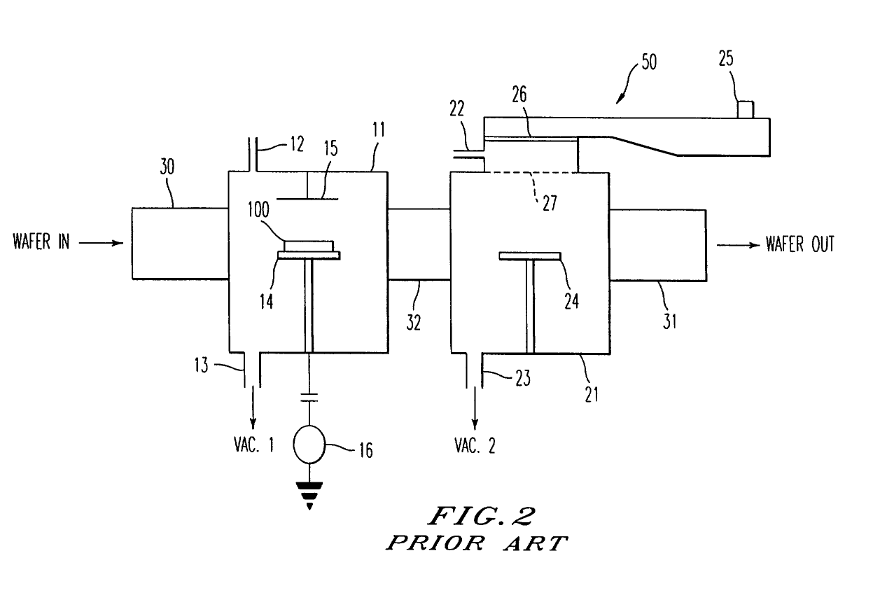

FIG. 3 is a top view of a processing system according to a first embodiment of the present invention;

FIG. 4 is a top view of a processing system according to a first embodiment of the present invention;

FIG. 5 is a component view of one embodiment of a chuck for use in the processing system of FIG. 3;

FIG. 6 is a cross-sectional view of a processing system utilizing exchangeable chucks according to a first embodiment of the present invention;

FIG. 7 is a top view of a processing chamber according to a second embodiment of the present invention; and

FIG. 8 is a top view of a processing system according to a third embodiment of the present invention.

### DESCRIPTION OF THE PREFERRED EMBODIMENTS

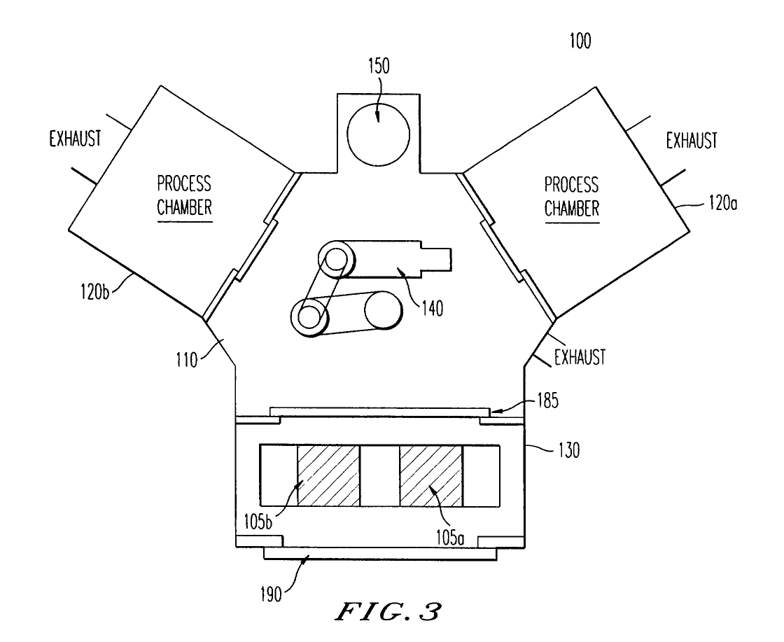

Referring now to the drawings, in which like reference numerals designate identical or corresponding parts throughout the several views, FIG. 3 is a schematic drawing of one embodiment of a plasma processing system 100. The illustrated system includes a loading cassette 105a, an unloading cassette 105b, a load lock chamber 110, at least one processing chamber 120, and a cassette chamber 130. A robotic arm 140 located in the load lock chamber 110 transfers the wafer (not shown) to/from the cassettes 105 and chambers (110, 120 and 130) during the processing cycles. A vacuum system (not shown) is connected to each chamber in order to provide the required vacuum conditions therein. Nitrogen gas lines (not shown) are connected to the load lock chamber 110 and the cooling chamber 130 for purging and venting purposes. Gas lines for delivering processing gases and/or liquid vapors are connected to the process chamber(s) 120.

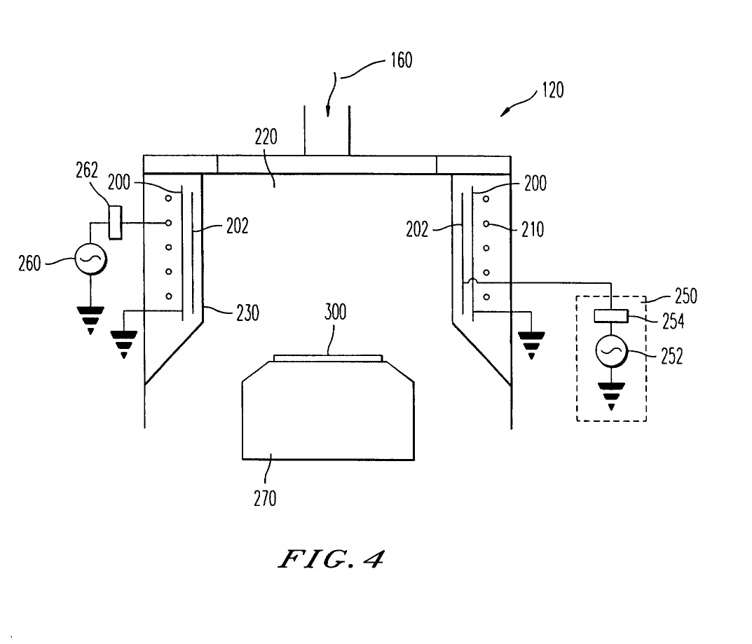

Heating or cooling mechanisms can also be installed in any of the processing, cooling and load lock chambers. For example, in one embodiment of the load lock chamber 110 of the present invention, shown in FIG. 3, a single preheating chuck 150 is included. The temperature of the preheating chuck 150 may be set to a value somewhat higher than the temperature of the processing chuck to compensate for the reduction of the wafer temperature during the transfer procedure. Similarly, in an alternate embodiment, if multiple wafers need to be pre-heated simultaneously, multiple pre-heating chucks 150a and 150b are included within the load lock chamber 110 or exterior to it for use in processes when it is advantageous to pre-heat multiple wafers simultaneously. As shown in FIG. 4, each processing chamber may have adjacent to it a next wafer pre-heating chamber, which may be either outside or within load lock chamber 110. As would be appreciated, the number of pre-heating stations is dictated by the relative wafer processing times in the process chambers and the relative time required for the wafer to attain the desired temperature on the pre-heating chucks. One exemplary use of the present invention is as a high-speed stripping (or ashing) chamber. By pre-heating the wafer outside of the process chamber, the stripping process can begin almost immediately after the wafer has entered the process chamber.

Pumping systems are installed for the load lock chamber and each of the processing chambers. The pumping system for the processing chambers is capable of reaching a pumping speed greater than 1000 liters/second (e.g., a Balzers-Pfeiffer Model TMH 1600). The high pumping speed increases the exchange rate of the reactive species and exhaust of the reaction products, enhancing the ashing process and improving the chamber cleanliness. FIG. 4 is a schematic drawing of one embodiment of an ESRF processing chamber 120 that may be used according to the invention. ESRF sources are described in U.S. Pat. Nos. 4,938,031 and No. 5,234,529. According to the present invention, a processing chamber 120 acts as a source plasma generating apparatus and includes a longitudinally split, metallic E-shield 200 disposed within a helical coil 210 and disposed around an internal plasma region 220. A ceramic, insulating wall 230 separates the plasma in the plasma processing region 220 and the coil 210.

The E-shield 200 provides a means to reduce coupling the RF power capacitively to the plasma, while at the same time it permits coupling the RF power inductively to the plasma from an RF power source 260. The vertical slits or slots in the E-shield 200 are designed to optimize the relative percentage of capacitively and inductively coupled RF power. The width, length and relative position of the E-shield and its slits or slots to the coil are particularly important as they directly affect the plasma property and process performance. To avoid difficulty in initiating plasma, but at the same time keep the plasma potential low, the combined area of the slits or slots should be above 0.1%, but less than 10% or tunable in-situ to minimize in the plasma ions with excess energy. In the preferred embodiment, the area of the slits or slots is between 0.2% and 5%.

The slotted E-shield 200 is electrically grounded. However, when the plasma system is operating in the system cleaning mode, an electrically biasable bias shield 202 is utilized to increase ion bombardment of the chamber walls and, hence, remove or clean the walls of deposited contaminants. In general, with reference to FIG. 4, the bias shield 202 is disposed between the E-shield 200 and the insulating wall 230, wherein the bias shield slots are aligned with the E-shield slots, however, the bias shield slots are typically wider. The bias shield 202 is connected to an external biasing circuit 250. The external biasing circuit 250 nominally comprises a RF generator 252 and match network 254. Additional details with respect to biasing the bias shield 202 can be found in the PCT patent application entitled “All-Surface Biasable and/or Surface Temperature Controlled Electrostatically-Shielded RF Plasma Source,” filed Nov. 13, 1998 (PCT US98/23248).

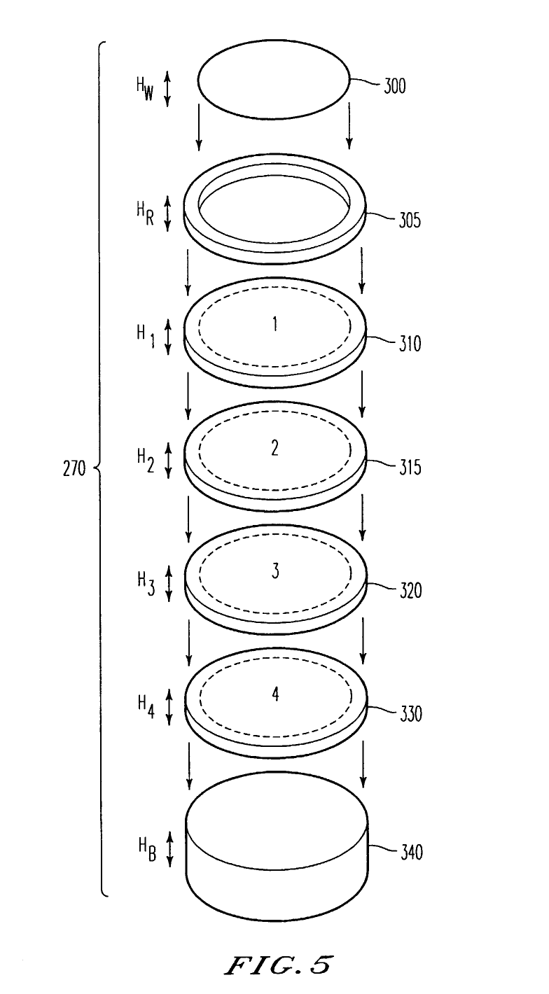

The wafer holder 270, on which the wafer is to be placed, is located in a lower portion of the chamber 120 and about 25 mm-50 mm below the lower end of the slots in the E-shield 200. FIG. 5 illustrates an embodiment of the wafer holder 270, and a detailed description 3of that design can be found in provisional application No. 60/156,595, filed Sep. 29, 1999, entitled “Multi-Zone Resistance Heater.” The wafer holder 270 includes a focus ring 305, an electrostatic clamping section 310, a He gas distribution system 315, a multizone resistance heater section 320, a multizone cooling system 330, and a base 340. The wafer 300 can be electrostatically clamped onto the holder 270 during processing. He gas is supplied to the region between the wafer 300 and the holder 270 to provide good thermal conduction between the two. The multizone resistance heater section 320 is used for rapidly heating up the wafer 300 to a desired temperature, and the cooling section 330 is used for rapidly cooling down the wafer to a desired temperature.

After processing, the wafer 300 is transferred back to the load lock chamber. The wafer 300 may then be moved to another process chamber 120 or through the loading door 185 to the unloading cassette 105b. Cassettes 105 are inserted and removed through the front door 190.

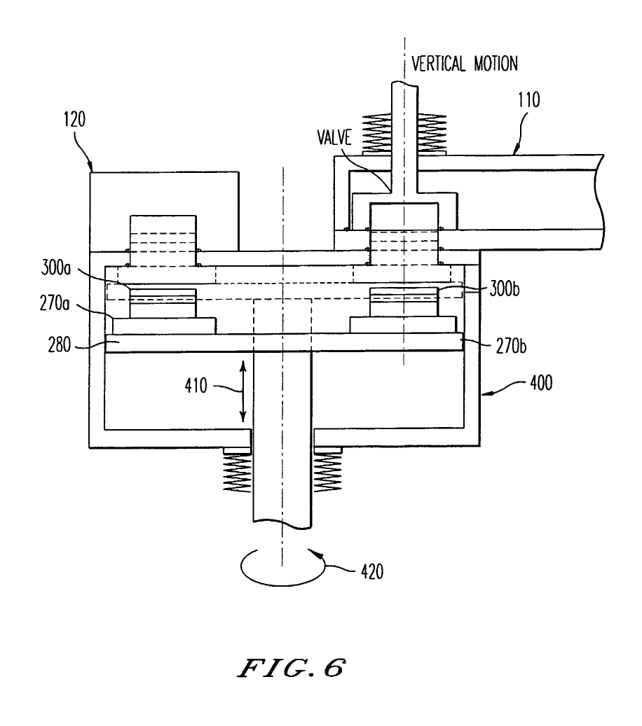

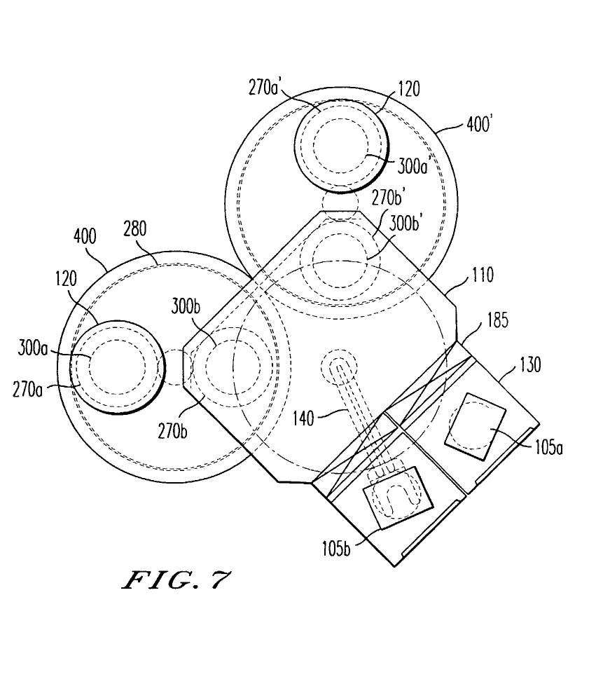

In still another embodiment of the invention, an exchangeable chuck arrangement, shown in FIG. 6, is incorporated in place of the optional preheater 150. FIG. 7 shows a top view of the exchangeable chuck arrangement. Two chucks, 270a and 270b, which hold wafers 300a and 300b, are situated in chamber 400 and have both vertical motion capability 410 and rotary motion capability 420. The wafer transfer arm 140 initially loads wafer 300b onto chuck 270b where it is electrostatically clamped and preheated. Once the processing being performed on wafer 300a is complete, the chuck assembly 280 is lowered using vertical motion capability 410, and chuck 270a with wafer 300a thereon are thereby withdrawn from process chamber 120. Chuck assembly 280 is then rotated through 180 degrees using rotary motion capability 420 and is raised using vertical motion capability 410 so that chuck 270b together with wafer 300b mounted thereon are thereby inserted into ESRF process chamber 120, while chuck 270a with wafer 300a mounted thereon are simultaneously inserted into transfer chamber 110. Wafer 300a is then withdrawn from chamber 400 by transfer arm 140 and returned to cassette 105b. While wafer 300b undergoes the intended process procedure (e.g., resist stripping), wafer transfer arm 140 removes a wafer 300c from cassette 105b and places it on chuck 270a where it is electrostatically clamped and preheated. When the processing of wafer 300b is complete, chuck assembly 280 is lowered using vertical motion capability 410 and rotated through 180 degrees using rotational motion capability 420. Chuck assembly 280 is then raised using vertical motion capability 410 and wafer 300b is unloaded from chuck 270b by transfer arm 140 and returned to wafer cassette 105b. The cycle is repeated until all wafers in cassette 105b have been processed.

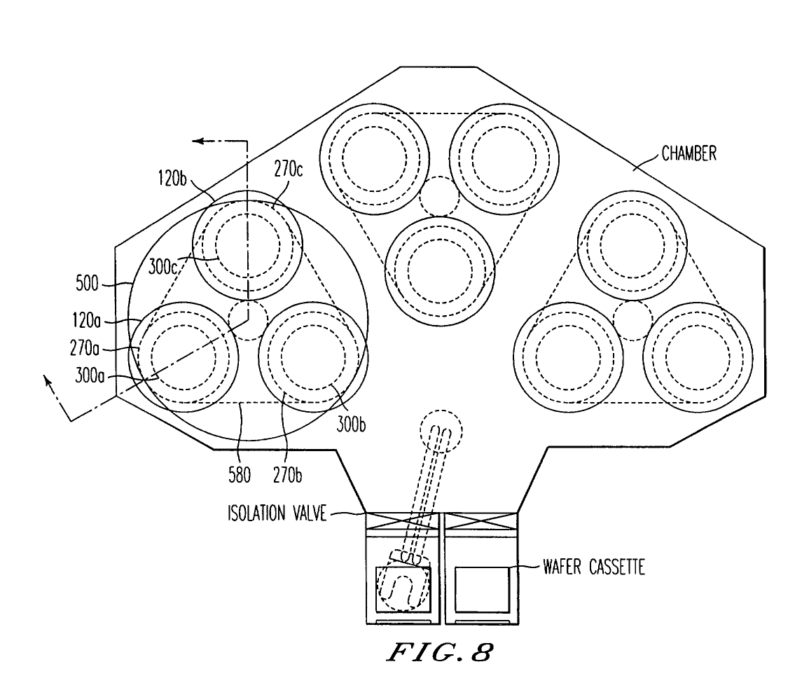

In yet another embodiment, as viewed from above in FIG. 8, a grouping of three chucks 270a, 270b, and 270c, with wafers 300a, 300b, and 300c respectively thereon, comprise a triple chuck assembly 580 in chamber 500. As with the dual chuck assembly 280, triple chuck assembly 580 has both vertical motion capability 410 and rotary motion capability 420. Two ESRF processing chambers 120a and 120b are provided. In general, these two ESRF processing chambers operate with different process chemistries. For example, ESRF process chamber 120a could be supplied with chemical agents suitable to reduce a carbonized ion-implanted crust on a photoresist, and ESRF chamber 120b with chemical agents suitable to oxidize and strip the photoresist. In an exemplary use of the system, a wafer 300b is loaded on chuck 270b by transfer arm 140 and preheated. When the processes in chambers 120a and 120b are complete, triple process chuck 580 is lowered using vertical motion capability 410, is rotated by 120 degrees using rotary motion capability 420, and then is raised using vertical motion capability 410 so that wafer 300b is located in ESRF processing chamber 120a. While wafer 300b is in ESRF processing chamber 120a, the carbonized ion-implanted crust on wafer 300b is reduced. When the reduction process is complete, triple process chuck 580 is again lowered using vertical motion capability 410, rotated 120 degrees using rotational capability 420, and raised using vertical motion capability 420 so that wafer 300b is relocated into ESRF processing chamber 120b. Chemical agents appropriate for stripping the photoresist are introduced into ESRF processing chamber 120b. When the stripping process is complete, triple process chuck 580 is again lowered using vertical motion capability 410, rotated 120 degrees using rotational motion capability 420, and raised using vertical motion capability 410. Wafer 300b, which has been stripped of the ion-implanted photoresist, may now be returned to wafer cassette 105b.

While the above description followed only wafer 300b, located on chuck 270b, though its processing, wafers 300a and 300c, located, respectively, on chucks 270a and 270c, undergo the same processing, albeit at different times.

Obviously, numerous modifications and variations of the present invention are possible in light of the above teachings. It is therefore to be understood that, within the scope of the appended claims, the invention may be practiced otherwise than as specifically described herein.

1. In a plasma processing system including a load lock chamber and a processing chamber, the improvement comprising:
a pre-heating wafer holder for pre-heating a substrate to be processed next in the processing chamber.

2. In the plasma processing system as claimed in claim 1, the improvement further comprising an electrostatic clamp integrated into the pre-heating wafer holder.

3. In a plasma processing system including a load lock chamber and a processing chamber, the improvement comprising:
a pre-heating wafer holder for pre-heating a substrate to be processed next in the processing chamber and for transferring with the substrate to be processed next into the processing chamber.

4. In the plasma processing system as claimed in claim 3, the improvement further comprising an electrostatic clamp integrated into the pre-heating wafer holder.

5. A method of stripping a photoresist layer in a plasma processing system, comprising the steps of:
(a) transferring a first substrate into a plasma chamber;
(b) stripping a resist from the first substrate in the plasma chamber;
(c) transferring a second substrate onto a pre-processing chuck outside of the plasma processing chamber; and
(d) pre-processing the second substrate on the pre-processing chuck, wherein step (b) and steps (c) and (d) are performed in parallel.

6. The method as claimed in claim 5, wherein the step of pre-processing comprises pre-heating the second substrate.

7. The method as claimed in claim 5, wherein the substrate comprises a semiconductor wafer.

8. The method as claimed in claim 5, wherein the substrate comprises a liquid crystal display panel.
